(19) United States
(12) Patent Application Publication
(10) Pub. No.: US 2023/0384391 A1
(43) Pub. Date: Nov. 30, 2023

(54) SYSTEMS AND TECHNIQUES FOR PREDICTING LIFE OF BATTERY, AND BATTERY MANAGEMENT SYSTEM OPERATING THE SAME

(71) Applicants: SK Innovation Co., Ltd., Seoul (KR); SK On Co., Ltd., Seoul (KR)

(72) Inventors: Ju Eun KWAK, Daejeon (KR); Kyung Min SONG, Daejeon (KR); Ky Sang KWON, Daejeon (KR)

(21) Appl. No.: 18/188,916

(22) Filed: Mar. 23, 2023

(30) Foreign Application Priority Data
May 31, 2022 (KR) 10-2022-0066935

(51) Int. Cl. G01R 31/392; G01R 31/367; G01R 31/371

(52) U.S. Cl. CPC G01R 31/392; G01R 31/367; G01R 31/371; B60L 58/16

(57) ABSTRACT

A method of predicting a battery lifespan includes estimating a state of health (SOH) of a battery by integrating an amount of electric current while a state of charge (SOC) of the battery mounted in each of a plurality of systems changes, dividing the plurality of systems into a plurality of groups according to a usage pattern collected by each of the plurality of systems at every predetermined period, generating a usage scenario of the battery in each of the plurality of systems, using a usage environment of each of the plurality of groups and the usage pattern, and predicting, for each of the plurality of systems, an end-of-life time of the battery using the usage scenario and the SOH of the battery.

### CROSS-REFERENCE TO RELATED APPLICATION(S)

This application claims the benefit of priority to Korean Patent Application No. 10-2022-0066935 filed on May 31, 2022 in the Korean Intellectual Property Office, the disclosure of which is incorporated herein by reference in its entirety.

### TECHNICAL FIELD

The present disclosure relates to systems and techniques for monitoring and managing rechargeable secondary batteries including systems and techniques for predicting life of a battery and a battery management system executing the same.

### BACKGROUND

A battery connected as part of an electrical power source for an electric vehicle, an energy storage device, and the like, includes one or more battery modules. One battery module may include a plurality of battery cells. A battery management system connected to the battery may collect various pieces of data for managing/monitoring the battery from its battery modules or battery cells.

### SUMMARY

Rechargeable secondary batteries in a battery system may have different lifespans depending on the usage of the battery system, charging habits, surrounding environment, or the like, and there is a need for a method for accurately predicting the end of lifespan of a battery.

An aspect of the present disclosure is to provide a method of predicting the lifespan of a battery, in which the battery may be stably operated and managed by accurately predicting the end of life of a battery based on measurable information from the battery, usage patterns of systems such as electric vehicles and energy storage devices equipped with batteries, the surrounding environment, or the like, and to provide a battery management system executing the method.

According to an aspect of the present disclosure, a method of predicting a battery lifespan includes estimating a state of health (SOH) of a battery by integrating an amount of electric current while a state of charge (SOC) of the battery mounted in each of a plurality of systems changes; dividing the plurality of systems into a plurality of groups according to a usage pattern collected by each of the plurality of systems at every predetermined period; generating a usage scenario of the battery in each of the plurality of systems, using a usage environment of each of the plurality of groups and the usage pattern; and predicting, for each of the plurality of systems, an end-of-life time of the battery using the usage scenario and the SOH of the battery.

According to an aspect of the present disclosure, a battery management system includes an SOH estimation model estimating an SOH of a battery by integrating an amount of electric current while an SOC of the battery mounted in each of a plurality of systems changes; a scenario generation model classifying the plurality of systems into a plurality of groups based on a usage pattern collected from each of the plurality of systems, and generating a usage scenario of the battery according to a usage environment and a usage pattern of each of the plurality of groups; and a lifespan prediction model predicting an end-of-life time of the battery using the SOH of the battery estimated by the SOH estimation model and the usage scenario.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic diagram illustrating an electric vehicle equipped with a battery management system according to an embodiment;

FIGS. 2A and 2B are diagrams illustrating a method of predicting a lifespan of a battery according to an embodiment;

FIG. 3 is a schematic block diagram illustrating a battery management system according to an embodiment;

FIGS. 4 to 6 are diagrams illustrating an example in which a method of predicting a lifespan of a battery according to an embodiment is applied to electric vehicles;

FIGS. 7 and 8 are diagrams illustrating an example in which a method of predicting a lifespan of a battery according to an embodiment is applied to energy storage systems;

FIG. 9 is a flowchart illustrating an example method of predicting a lifespan of a battery according to an embodiment;

FIG. 10 is a diagram illustrating another example method of predicting a lifespan of a battery according to an embodiment;

FIG. 11 is a flowchart illustrating yet another example method of predicting a lifespan of a battery according to an embodiment; and

FIG. 12 is a diagram illustrating yet another example method of predicting the lifespan of a battery according to an embodiment.

### DETAILED DESCRIPTION

The technology disclosed in this patent document is directed to operating and managing rechargeable batteries (including, e.g., lithium ion batteries) in a battery system. Various features of disclosed embodiments of the disclosed technology, and methods of obtaining the same, and certain advantages associated with specific implementations of the disclosed technology are described below with reference to the detailed description set forth below in conjunction with the accompanying drawings.

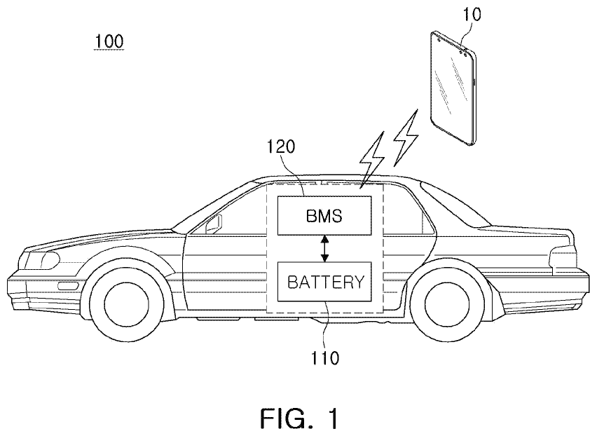

FIG. 1 is a diagram schematically illustrating an electric vehicle equipped with a battery management system according to an embodiment.

Referring to FIG. 1, an electric vehicle 100 may include a battery 110 and a battery management system 120. The battery management system 120 is referred to as BMS (a battery management system), and may control charging and discharging of the battery 110. In addition, the battery management system 120 may monitor the state of charge and the remaining life of the battery 110, and output the state of charge, remaining life, and the like, to the owner or driver of the electric vehicle 100 through the display inside the electric vehicle 100 and/or a user terminal that interfaces with the electric vehicle 100.

The battery 110 may be implemented as a battery pack having a plurality of battery modules, and each of the plurality of battery modules may include a plurality of battery cells. For example, each of the plurality of battery cells includes a case, a positive electrode, and a negative electrode, an electrolyte solution, and a separator that is disposed between the positive electrode and the negative electrode inside the case. In a case in which the battery 110 is a lithium ion battery, in the charging operation, lithium ions released from the positive electrode may be concentrated on the negative electrode through the separator, and in the discharging operation, lithium ions released from the negative electrode may pass through the separator and be concentrated on the positive electrode.

Due to the characteristics of the electric vehicle 100 that provides driving and various other functions during the operation of the vehicle by using the battery 110 as a power source, it is necessary or desirable to accurately estimate or predict the lifespan of the battery 110 connected as part of an electrical power source for the electric vehicle 100. However, in operating the electric vehicle 100, the driving environment and driving pattern may be greatly changed either because the owner or driver may adjust his or her specific driving operations to meet the specific needs or respond to changes in the driving conditions or the surrounding environment of the vehicle, or because different or owners or drivers operate the vehicle. Therefore, to accurately predict the lifespan of the electric vehicle 100, it may be necessary or desirable to consider not only internal variables of the electric vehicle 100 itself, such as the charging/discharging pattern of the battery 110 and the driving distance of the electric vehicle 100, but also external variables such as the driving environment or changes in driving patterns.

In an embodiment, a usage scenario of the battery 110 is determined according to the driving profile and driving environment of the electric vehicle 100, and data that may be input into a machine learning model may be processed based on usage scenarios. This processed data may be input into the machine learning model together with the data that may be calculated from the battery 110, and thus, the end of the life of the battery 110 may be predicted. In addition, by monitoring the driving profiles and driving environment changes of the electric vehicle 100 and updating the usage scenario of the battery 110 at regular intervals, the lifespan information including the end point of the lifespan of the battery 110 may be accurately predicted despite changes in various external variables. The battery management system 120 may predict the end of lifespan in a predetermined cycle, for example, in units of a week or a month.

For example, the battery management system 120 may accumulate the amount of an electric current of the battery 110 while the state of charge (SOC) of the battery 110 changes, and may estimate the state of health (SOH) of the battery 110 using the SOC change amount and the electric current integration amount. In addition, the battery management system 120 collects the usage pattern and usage environment of the electric vehicle 100, and may directly create a usage scenario of the battery 110 by using the collected information. In this case, the lifespan prediction model mounted on the battery management system 120 receives the processed data from the usage scenario and the SOH of the battery, and predicts the end of life of the battery 110, and may output the same to the display of the electric vehicle 100, the user terminal 10, or the like.

According to an embodiment, the battery management system 120 transmits a usage pattern, usage environment and the like to an external server, which may be configure to create usage scenarios. In this case, the external server may estimate the SOH estimated from the battery 110 together with data related to the usage pattern and usage environment of the electric vehicle 100. Therefore, the external server predicts the end of the life of the battery 110 by inputting the data processed from the usage scenario and the SOH of the battery to the pre-trained lifespan prediction model, and may transmit the same to the electric vehicle 100, the user terminal 10 or the like.

In an embodiment, the lifespan prediction model may operate in association with one or more other machine learning models. As an example, in addition to the lifespan prediction model, a scenario generation model for generating a usage scenario according to a usage pattern and usage environment of the electric vehicle 100, an SOH estimation model for estimating the SOH of the battery 110 based on the amount of the accumulated electric current of the battery 110, and the like may operate in conjunction with the lifespan prediction model. In an example, the SOH estimation model includes a first SOH estimation model and a

second SOH estimation model. The first SOH estimation model may be a model for estimating the SOH of the battery 110 using physical data related to physical information collected in the design and manufacturing stages of the battery 110. On the other hand, the second SOH estimation model may be a model for estimating the SOH of the battery 110 using field data collected while the battery 110 is being charged and discharged. Accordingly, the SOH estimated by the first SOH estimation model and the SOH estimated by the second SOH estimation model for the same battery 110 at the same time may be different from each other.

At an initial point in time, immediately after the electric vehicle 100 is shipped, there may be no field data collected while the battery 110 is being charged and discharged. Therefore, to accurately predict the remaining lifespan of the electric vehicle 100 at the initial time point, data other than the field data directly collected from the battery 110 may be used.

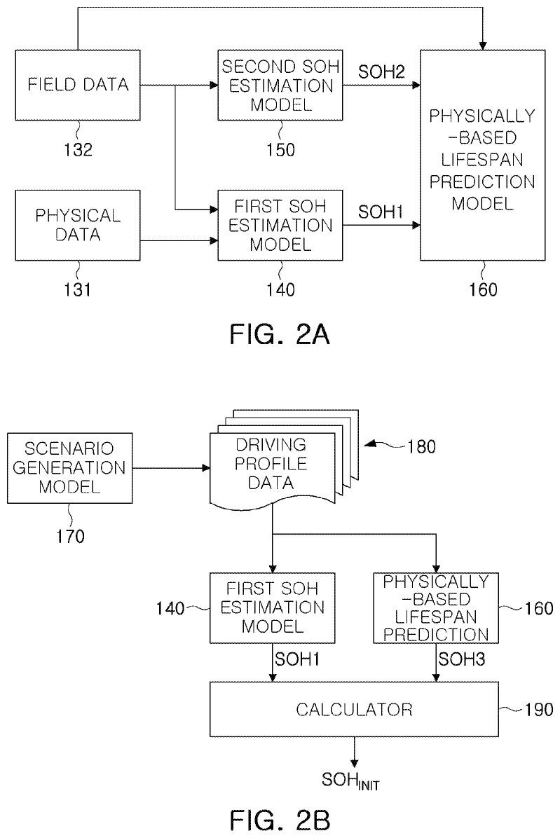

FIGS. 2A and 2B are diagrams illustrating a method for predicting the remaining lifespan of the battery 110 at an initial time point immediately after the electric vehicle 100 is shipped. FIG. 2A is a diagram illustrating a learning method of a physical information-based lifespan prediction model for predicting the remaining lifespan of the battery 110 at an initial time point, and FIG. 2B is a diagram illustrating a method for predicting the remaining lifespan of the battery 110 at an initial time point.

First, referring to FIG. 2A, a first SOH estimation model 140 may be a model receiving physical data 131 corresponding to physical information collected during the design and manufacturing phase of the battery 110 to estimate the SOH of the battery 110. The second SOH estimation model 150 may be a model for estimating the SOH of the battery 110 by receiving field data 132 collected while the battery 110 is in use. In the initial stage, the first SOH estimation model 140 receives the physical data 131 related to the physical information of the battery 110, and may output a first SOH estimate SOH1. On the other hand, the second SOH estimation model 150 may output a second SOH estimate SOH2 obtained by evaluating the initial SOH of the battery 110 based on a predetermined SOH estimation logic.

The first SOH estimate SOH1 and the second SOH estimate SOH2 may be used as inputs to a physical information-based lifespan prediction model 160, as a response variable. As an example, the difference between the first SOH estimate SOH1 and the second SOH estimate SOH2 may be applied as a response variable of the physical information-based lifespan prediction model 160. The physical information-based lifespan prediction model 160 may perform learning by selecting the difference between the first SOH estimate SOH1 and the second SOH estimate SOH2 as a response variable and by selecting a deterioration factor of the battery 110 and the like as explanatory variables.

The battery management system 120 may predict the remaining lifespan of the battery 110 at an initial time point corresponding to immediately after shipment of the electric vehicle 100, using the physical information-based lifespan prediction model 160, which has been trained. Referring to FIG. 2B, a first scenario generation model 170 may output driving profile data 180 corresponding to a future usage scenario. As an example, the scenario generation model 170 may output driving profile data 180, based on data generated from the past driving history of the customer who purchased the electric vehicle 100, data of other customers who have purchased a vehicle similar to the electric vehicle 100, or the like.

The driving profile data 180 may be input to the first SOH estimation model 140 and the physical information-based lifespan prediction model 160. The first SOH estimation model 140 may output the first SOH estimate SOH1 based on the driving profile data 180, and the physical information-based lifespan prediction model 160 may output a third SOH estimate SOH3. As an example, the third SOH estimate SOH3 output by the physical information-based lifespan prediction model 160 is a response variable, and may correspond to a difference between the SOH of the battery predicted based on the physical data as described above with reference to FIG. 2A, and the SOH of the battery evaluated by the SOH estimation logic.

As an example, in an embodiment illustrated in FIG. 2B, a calculator 190 may output the sum of the first SOH estimate SOH1 and the third SOH estimate SOH3 as an initial SOH value SOH_{INIT} of the battery 110. The end-of-life time of the battery 110 may be defined as the time remaining for the SOH of the battery 110 to decrease to a predetermined threshold value, and therefore, it is very important to accurately estimate the SOH initial value SOH_{INIT} of the battery 110. As described with reference to FIGS. 2A and 2B, the physical information-based lifespan prediction model may be trained with the SOH estimates calculated by using physical data related to the physical information of the battery 110 and field data collected from other electric vehicles by other users, and the SOH initial value SOH_{INIT} of the battery 110 may be accurately estimated using the learned physical information-based lifespan prediction model. The lifespan prediction model may determine a decreasing trend of the SOH of the battery 110 to predict the end-of-life time. The lifespan prediction model may continuously perform learning by comparing the decreasing trend of SOH with the actual decreasing trend of SOH according to the accumulated use time of the electric vehicle 100. Therefore, as time elapses, the learning (or online training) of the lifespan prediction model is based on data according to the actual usage pattern and actual usage environment of the electric vehicle 100, and therefore, the end of life may be accurately predicted.

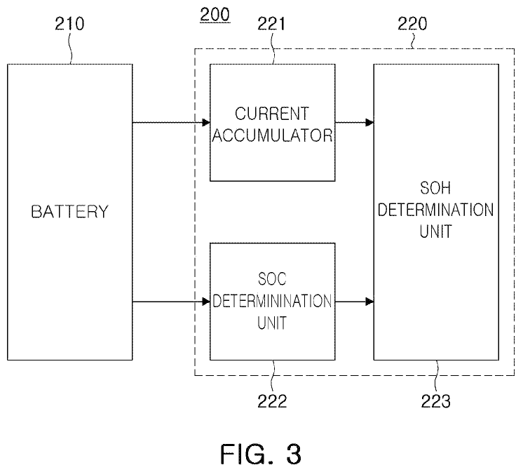

FIG. 3 is a block diagram schematically illustrating a battery management system according to an embodiment.

Referring to FIG. 3, a system 200 according to an embodiment includes a battery 210 and a battery management system 220, and the battery management system 220 may include an electric current accumulator 221, an SOC determination unit 222, and an SOH determination unit 223. The electric current accumulator 221 may calculate discharge energy or charge energy of the battery 210 during the corresponding time period, by integrating the electric current consumed by the battery 210 for a predetermined period of time or the electric current that charges the battery 210.

The SOC determination unit 222 and the electric current accumulator 221 may determine the decrease or increase in the SOC of the battery 210 during the electric current integration time. The SOH determination unit 223 may estimate the SOH of the battery 210 by comparing the discharge energy or the charging energy calculated by the electric current accumulator 221 with the amount of change in the SOC of the battery 210.

As an example, during the time the SOC of the battery 210 decreases by 30%, the electric current accumulator 221 may integrate the electric current consumed by the battery 210 and calculate the discharge energy of the battery 210. By substituting this into Equation 1 below, the total energy (Etotal) of the battery 210 may be calculated when the SOC is 100%.

SOC change: energy change=100%: Etotal (1)

The SOH determination unit 223 compares the total energy Etotal of the battery 210 calculated by Equation 1 with the total energy immediately after shipment of the battery 210 and/or the system 200, thereby determining SOH. For example, when the total energy (Etotal) of the battery 210 calculated at the current time by Equation 1 is 0.9 times the total energy at the time immediately after shipment of the system 200 including the battery 210, the SOH of the battery 210 at the present time may be calculated as 90%. The SOH at the current time calculated by the SOH determiner 223 may be used to predict

the end of life of the battery 210. As an example, the battery management system 220 may directly acquire the usage scenario of the battery 210 according to the usage pattern and usage environment of the system 200 and the like, and extract data in a form that may be input into the lifespan prediction model from the usage scenario. The battery management system 220 inputs the extracted data to the lifespan prediction model, together with the SOH at the current time calculated by the SOH determination unit 223, to determine the decreasing trend of SOH and predict the end of lifespan therefrom. In determining the decreasing trend of SOH, the initial value of SOH calculated as described above with reference to FIGS. 2A and 2B may be utilized. In an embodiment, the end of life of the battery 210 may be determined according to a Remaining Useful Life (RUL), which is a time remaining until the SOH of the battery 210 decreases from the current time point to a specific value, for example, 80%.

Alternatively, as described above, the lifespan prediction model may be stored in a separate server capable of communicating with the system 200. In this case, the battery management system 220 may transmit the usage environment and usage pattern of the system 200 together with the SOH of the battery 210 determined at the current time point to the server. The server may create a usage scenario based on the usage environment and usage pattern of the system 200, input the data extracted from the usage scenario together with the SOH of the battery 210 into the lifespan prediction model, and predict the end of the life of the battery 210.

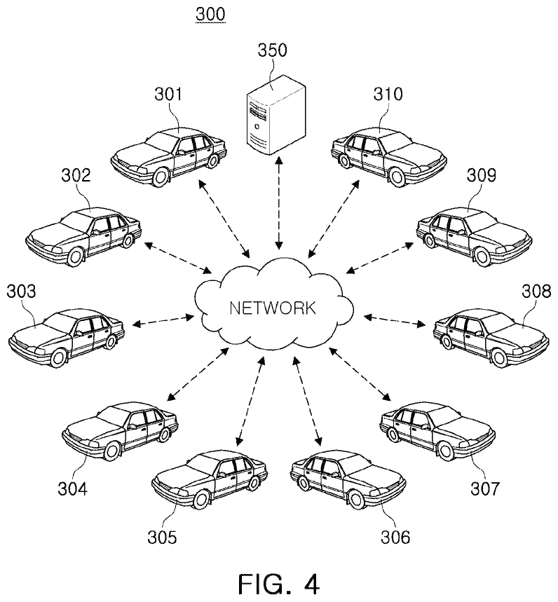

FIGS. 4 to 6 are diagrams illustrating an example in which a method of predicting a lifespan of a battery according to an embodiment is applied to electric vehicles. Referring first to FIG. 4, a plurality of electric vehicles 301-310 may be connected to a

server 350 through a network. The server 350 may store the lifespan prediction model as described above, and may predict the end of life of the battery mounted in the plurality of respective electric vehicles 301-310 to provide the predicted life end time to the owner and/or user of each of the plurality of electric vehicles 301-310. For example, each of the plurality of electric vehicles 301-310 may be equipped with a

battery management system together with a battery as a power source. The battery management system integrates the electric current consumed by the battery during use of the battery, and the SOH of the battery may be calculated at a specific point in time by using the SOC of the battery that has decreased during the time for which the accumulated electric current is acquired. In addition, the battery management system collects the usage patterns and usage environments of the respective electric vehicles 301-310 determined from the charging/discharging patterns of the batteries, or the like, processes the same in the form of data, and may transmit the same to the server 350 through the network together with the SOH. For example, the battery management system may collect the SOH of the battery and the usage pattern and usage environment of the respective electric vehicles 301-310 every predetermined interval and transmit the same to the server 350.

The server 350 may classify the electric vehicles 301-310 into a plurality of groups based on a usage pattern and usage environment of each of the electric vehicles 301-310. For example, the plurality of groups for classifying the electric vehicles 301-310 may include a business group, a household group, and the like that are classified according to the use of each of the electric vehicle 301-310. Alternatively, the household group may be further divided into sub-groups such as a commuting group and a leisure group.

On the other hand, the electric vehicles 301-310 may be classified according to usage environments and other factors in addition to the use. For example, according to a main driving area (operating region) of the electric vehicles 301-310, the vehicles may be divided into an urban group and a local group.

As a specific example for classifying or grouping the plurality of electric vehicles 301-310 into a plurality of groups, a usage pattern of each of the plurality of electric vehicles 301-310 may be used. Each of the charging pattern, discharging pattern, and resting pattern of the battery mounted in each of the plurality of electric vehicles 301-310 is extracted as data, which may be processed by a Gaussian mixture model, as an example, to enable the plurality of electric vehicles 301-310 to be divided into a plurality of groups.

A different usage scenario may be applied to the respective groups in which the electric vehicles 301-310 are divided. For example, in the case of some electric vehicles divided into an urban group or a commuting group, in a usage scenario, rapid acceleration/braking and charging cycles may be set to be relatively short. On the other hand, in the usage scenario of some electric vehicles classified into the local group, the constant speed driving may be relatively more and the charging period may be set relatively long. For electric vehicles in the commercial group, the driving time and distance may be set relatively longer than those in the household group.

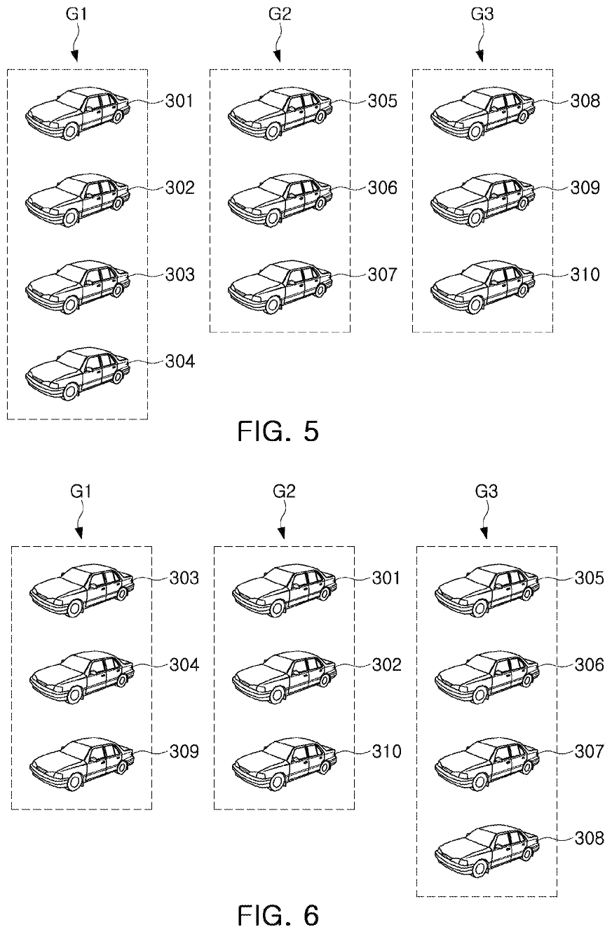

FIGS. 5 and 6 may be diagrams illustrating a grouping method of electric vehicles 301-310. Referring to FIGS. 5 and 6, as illustrated in FIG. 4, a plurality of electric vehicles 301-310 connected to the server 350 through a network may be divided into a total of three groups G1-G3.

However, this is only an embodiment, and according to embodiments, the server 350 may classify the electric vehicles 301-310 into four or more groups.

For example, a first group G1 may be a commuting group mainly operated in the city center, a second group G2 may be a leisure group, and a third group G3 may be a business group mainly operated in the city center. Accordingly, the server 350 may apply different usage scenarios to the respective first to third groups G1-G3.

The embodiment illustrated in FIG. 5 may be an example in which at the time of shipment of the plurality of electric vehicles 301-310, the server 350 divides the plurality of respective electric vehicles 301-310 into the first to third groups G1-G3. As an example, at a time when the plurality of electric vehicles 301-310 are shipped, according to the residence, occupation, or the like of the buyer who purchased each of the plurality of electric vehicles 301-310, each of the plurality of electric vehicles 301-310 may be classified as belonging to one of the first to third groups G1-G3. Referring to FIG. 5, the first to fourth electric vehicles 301-304 are classified as the first group G1, the fifth to seventh electric vehicles 305-307 may be classified as the second group G2, and the eighth to tenth electric vehicles 308 to 310 may be classified as the third group G3.

The server 350 may receive the usage pattern and usage environment of each of the electric vehicles 301-310 from the battery management system of each of the plurality of electric vehicles 301-310 at predetermined intervals, together with the SOH estimated for the batteries mounted in the respective electric vehicles 301-310. Also, the server 350 may newly classify the plurality of electric vehicles 301-310 into the first to third groups G1-G3 for each corresponding cycle or whenever a predetermined number or more cycles are accumulated.

Referring to FIG. 6, as a predetermined period elapses, the server 350 uses data such as a use pattern and a use environment collected during one period to newly classify the plurality of electric vehicles 301-310 into first to third groups G1-G3. For example, due to changes in circumstances, such as when the owner of an electric vehicle changes, main residence or workplace of the owner of the electric vehicle changes or the owner of the electric vehicle purchases an additional vehicle; the usage environment and usage patterns of the plurality of electric vehicles 301-310 may change.

For example, when an owner who purchased the first electric vehicle 301 for commuting to and from work in the city center purchases an additional vehicle and uses the first electric vehicle 301 for leisure, the server 350 may reclassify the first electric vehicle 301 as the second group G2 according to a change in the usage pattern of the first electric vehicle 301. Similarly, for example, when a ninth electric vehicle 309 sold for business use at the beginning of sales is sold to another owner for general commuting, the server 350 may reclassify the ninth electric vehicle 309 as the first group G1 according to the changed usage pattern of the ninth electric vehicle 309.

The server 350 receives the SOH of the battery estimated by the battery management system in each of the plurality of electric vehicles 301-310 at predetermined intervals, while may extract data from a usage scenario applied to each of the plurality of groups G1-G3. For example, data such as the charging speed of the battery, statistics on acceleration determined from the driving history of each of the electric vehicles 301-310 and energy consumption may be extracted and input into the lifespan prediction model. For example, the charging speed of the battery may include the number of rapid charging and slow charging, and the like, and the statistics on acceleration may include the number of rapid acceleration driving, constant driving time and the like. The server 350 may input the data extracted from the usage scenario and the SOH of the battery to the pre-trained lifespan prediction model, and predict the end of life of the battery installed in each of the plurality of electric vehicles 301-310.

By sensing a change in the usage pattern and usage environment of the plurality of respective electric vehicles 301-310 at predetermined intervals, the plurality of electric vehicles 301-310 are reclassified, and also, since the end of life of the battery is predicted by receiving the SOH of the battery that has decreased during one cycle, the accuracy of end-of-life prediction may be improved. In this case, the server 350 may predict the end time of life in the unit of the cycle.

For example, when the server 350 predicts the end of life of the battery installed in each of the plurality of electric vehicles 301-310 every week, the server 350 may predict the end-of-life time on a weekly basis and notify the predicted end time of the battery life to the owner of each of the electric vehicles 301-310.

The usage pattern periodically received from the battery management system of each of the plurality of electric vehicles 301-310 may include a charging pattern and a discharging pattern of battery mounted in each of the electric vehicles 301-310. For example, the discharge pattern may include the number of rapid and slow charging times of the battery, the charging cycle, the parking time at which the battery is naturally discharged, the mileage, driving profiles such as the number of times of rapid acceleration/braking during driving and the constant speed driving distance, and the like. The use environment may include the driving environment of the electric vehicles 301-310, for example, weather, average temperature, daily temperature difference, annual temperature difference, and the like of a region in which the electric vehicles 301-310 are mainly operated.

The server 350 may configure a usage scenario for each of the first to third groups G1 to G3, using a usage pattern and usage environment, for example, respective uses, driving profile, mileage, driving environment, charging habit, or combinations thereof of the plurality of electric vehicles 301-310. The server 350 may extract data that may be input to the lifespan prediction model pre-trained in the usage scenario, and may predict the end-of-life time of the battery by inputting the extracted data into the lifespan prediction model together with the SOH estimate of the battery installed in each of the plurality of electric vehicles 301-310.

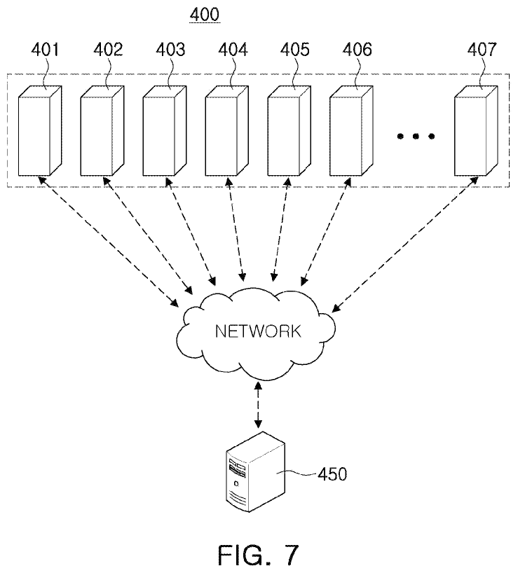

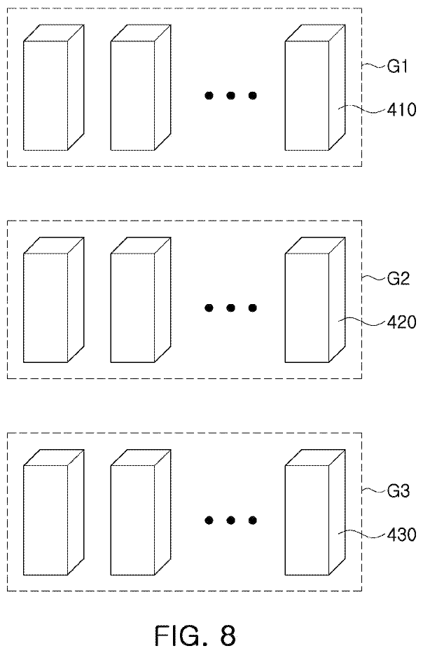

FIGS. 7 and 8 are diagrams illustrating an example in which a method of predicting a lifespan of a battery, according to an embodiment, is applied to energy storage systems.

Referring to FIG. 7, a plurality of energy storage devices 401-407 may be connected to a server 450 through a network. The server 450 stores the lifespan prediction model as described above, and predicts the end-of-life time of the battery connected in each of the plurality of energy storage devices 401-407 to provide the predicted result to the administrator of each of the plurality of energy storage devices 401-407.

For example, each of the plurality of energy storage devices 401-407 may have a battery and a battery management system mounted therein. A battery may be mounted in each of the plurality of energy storage devices 401-407 in units of a battery rack. The battery management system may calculate the SOH of the battery at a specific point in time by integrating the electric current consumed by the battery and using the SOC of the battery that has decreased during the time the accumulated electric current is acquired. According to an embodiment, to accurately calculate the SOH of the battery, the battery management system may calculate the SOH of the battery after the battery enters a stable state.

In addition, the battery management system collects the usage patterns and usage environments of the plurality of respective energy storage devices 401-407, determined from the battery charge/discharge patterns, or the like, at predetermined intervals, and processes the collected data to transmit the processed data together with the SOH to the server 450 through the network. The server 450 may configure a usage scenario based on a usage pattern and a usage environment of each of the energy storage devices 401-407, and classify the energy storage devices 401-407 into a plurality of groups.

For example, the energy storage devices 401-407 may be divided into an industrial group, a household group, an electric vehicle charging group, and the like, and a different usage scenario may be applied to respective groups. In addition, the respective energy storage devices 401 to 407 may be divided into regions according to a surrounding environment rather than a purpose of use.

The energy storage devices 401-407 may be classified into a plurality of groups based on a reference, e.g., the surrounding environment, the average temperature, the daily temperature difference, the annual temperature difference, or the like.

Referring to FIG. 8, the server 450 may classify the plurality of energy storage devices into first to third groups G1-G3. For example, the first group G1 may be an industrial group, and energy storage devices 410 used as power sources for supplying power at an industrial site may be classified as the first group G1. The second group G2 may be a household group, and energy storage devices 420 used for storing electrical energy and supplying power in a general home may be classified as the second group G2. On the other hand, the third group G3 is a group for charging an electric vehicle, and energy storage devices 430 disposed in an electric vehicle charging station may be classified as the third group G3.

The first to third groups G1 to G3 may respectively have a different usage pattern. For example, the energy storage devices 420 of the second group G2, which is a household group, may be mainly charged during a time period when electricity usage is relatively low, for example, a nighttime period, and may be discharged a lot during the daytime period. On the other hand, the third group G3, which is a group for charging electric vehicles, may be mainly discharged during nighttime when electric vehicles are not driven, for charging electric vehicles.

Accordingly, the server 450 may configure different usage scenarios for the first to third groups G1 to G3 respectively, extract data that may be input into the lifespan prediction model based on the usage scenario, and input the data to the lifespan prediction model. For example, an

SOC profile of a battery according to a usage scenario may be extracted as data and input to a lifespan prediction model. The lifespan prediction model may receive the data extracted from the usage scenario and the SOH of the battery predicted by the battery management system from each of the energy storage devices 410-430, and may predict the end-of-life time point at which the SOH of the battery decreases to a threshold value. The lifespan prediction model may predict the end of life in units of a cycle in which the server 450 receives the SOH of the battery, a usage pattern for configuring a usage scenario, a usage environment, and the like from the energy storage devices 410-430.

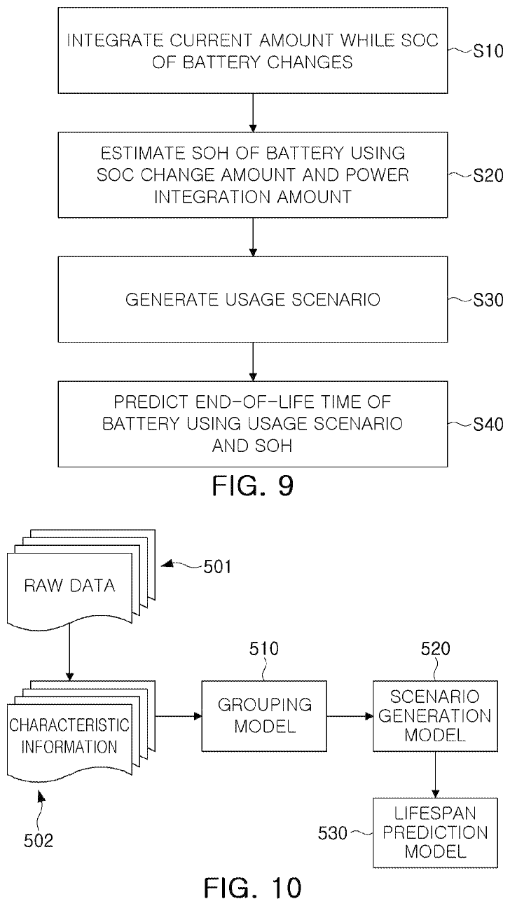

FIG. 9 is a flowchart illustrating a method of predicting the lifespan of a battery according to an embodiment. Referring to FIG. 9, a method for predicting the lifespan of a battery according to an

embodiment may start with the battery management system accumulating the amount of electric current of the battery while the SOC of the battery is changed (S10). For example, the battery management system may accumulate the amount of electric current of the battery while the battery is being charged and the SOC is increased, or may accumulate the amount of electric current of the battery while the SOC is decreased as the battery is discharged.

The battery management system may estimate the SOH of the battery using the electric current integration amount and the SOC change amount (S11). However, to accurately calculate the amount of change in the SOC of the battery, the SOC of the battery may be measured after the battery enters the stabilization state. For example, in the case of an electric vehicle, the SOC change amount may be calculated by measuring the SOC of the battery after the electric vehicle stops driving and is parked and a predetermined time has elapsed. In the case of measuring SOC from the open circuit voltage (OCV) of the battery or the like, the SOC may not be accurately measured if the battery does not enter the stable state.

When the SOH of the battery is calculated, the server may generate a battery usage scenario (S12). For example, the server may receive data indicating a usage pattern and usage environment of a battery-mounted system, for example, an electric vehicle or an energy storage device, from the battery management system, and generate a usage scenario based thereon.

The server may predict the end-of-life time of the battery by using the usage scenario and the SOH of the battery (S13). For example, based on the SOH of the battery at the current point in time calculated in operation S11, the lifespan prediction model may be trained to predict the decreasing trend of the SOH of the battery based on data extracted from the usage scenario. The end-of-life time of the battery may be a time when the SOH of the battery decreases to a predetermined threshold value, and thus, the end-of-life time of the battery may be predicted using the current value and decreasing trend of the SOH.

FIG. 10 is a diagram illustrating a method of predicting the lifespan of a battery according to an embodiment.

Referring to FIG. 10, to implement the method of predicting a lifespan of a battery according to an embodiment, a server connected to a plurality of systems in which a battery is respectively connected as part of the electrical power source, through a network, may extract characteristic information 502, corresponding to a predetermined unit period, from raw data 501. The characteristic information 502 may be extracted for the entire period during which the systems are operated with the battery power, or for a recent part of the entire period. For example, when each of the systems is an electric vehicle, information related to a usage pattern of the electric vehicle may be extracted as the characteristic information 502 from the raw data 501. The raw data 501 may be collected from field data while battery-equipped systems are operated. The extracted characteristic information 502 may be used to group a plurality of systems.

For example, when each of the systems is an electric vehicle, grouping by a grouping module 510 may be performed according to whether the driving environment of each electric vehicle is in the city center, whether the use of each electric vehicle is for commuting or leisure, or the like. In the case of existing systems among a plurality of systems, grouping may be performed based on the characteristic information 502 extracted from the raw data 501 of each of the existing systems. In the case of newly added systems, grouping may be performed by comparing the characteristic information 502 with existing systems belonging to respective groups.

When each of the systems is an electric vehicle and a new vehicle with no driving history is added, grouping may be performed, by using the physical information collected in the design and manufacturing stage of the battery mounted in the electric vehicle, as the characteristic information 502. Alternatively, a new electric vehicle may be grouped using the raw data 501 that is field data collected from other existing electric vehicles. For example, among existing electric vehicles, the new electric vehicles may be grouped by referring to load information such as driving distance and driving time obtained from other electric vehicles similar to the new electric vehicle.

When the grouping is completed, a scenario generation model 520 may generate a usage scenario for each group or each system. The scenario generation model 520 may output data corresponding to a usage scenario, and the data output from the scenario generation model 520 may have a format that may be input to the lifespan prediction model 530. For example, data output by the scenario generation model 520 may include charging patterns and discharging patterns of systems belonging to respective groups, and the like. The lifespan prediction model 530 may estimate the future SOH change amount of each

of the systems from the data output by the scenario generation model 520, and predict the remaining useful life (RUL) of the battery therefrom. The remaining useful life (RUL) of a battery is the time from the current point of time until the end of the battery life, and the server that provides the lifespan prediction method may provide the end-of-life time point of the battery itself or may provide the remaining useful life (RUL), which is the remaining period until the end-of-life time point.

For example, the server may estimate the SOH at the current time based on the SOC and the electric current integration amount obtained from the battery, and periodically generate a usage scenario according to a usage pattern, usage environment, and the like. In addition, the server may calculate the remaining useful life (RUL) for each period and provide the calculated RUL to the owner and/or administrator of the system. The remaining useful life (RUL) may be calculated as a time remaining until the SOH decreases to a lower limit value corresponding to the end-of-life time when a usage scenario is applied to the SOH at the current time point. For example, the cycle may be set to one week, one month, or the like. By synthesizing and using the data accumulated during the preset period as described above, the calculation efficiency of the server may be improved.

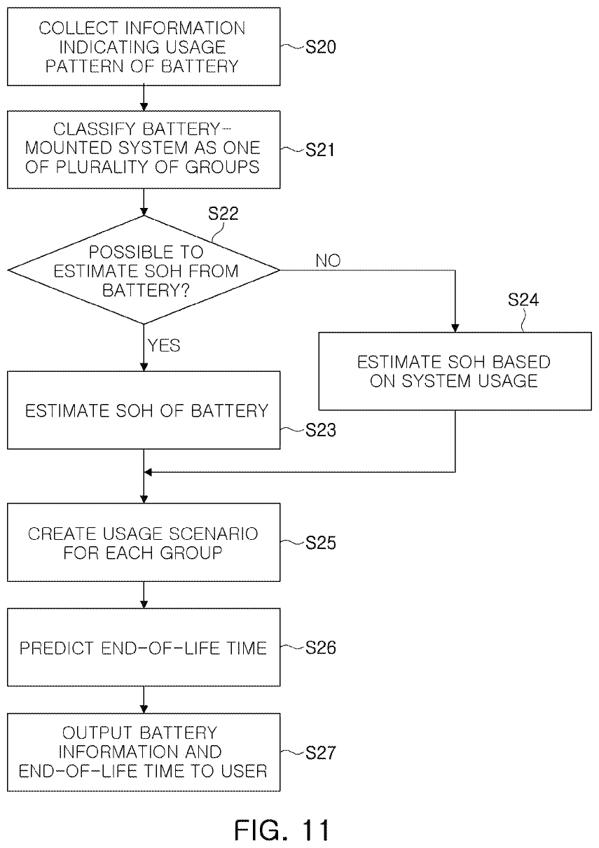

FIG. 11 is a flowchart illustrating a method of predicting the lifespan of a battery according to an embodiment.

In an embodiment, and referring to FIG. 11, the method of predicting the lifespan of a battery may be executed in a server connected to systems in which batteries are respectively mounted, by a network. The server may collect information indicating a usage pattern of the battery to predict the lifespan of the battery mounted in each of the systems (S20). For example, in operation S20, a usage pattern according to a system in which the battery is mounted may be collected. For example, when a battery is installed in an electric vehicle, information such as a driving distance of the electric vehicle, a charging pattern, and a driving pattern such as sudden acceleration/braking may be collected as a usage pattern.

When the usage pattern is collected, the server may classify the battery-mounted system as one of a plurality of groups (S21). When the server is connected to a plurality of systems through a network, the plurality of systems may be divided into a plurality of groups. For example, when the systems are electric vehicles, the electric vehicles may be divided into a business group and a household group according to the driving distance, and may be divided into a commuting group and a leisure group according to the number of rapid acceleration/braking instances.

Once the grouping of systems is complete, the server may estimate the SOH from the battery. As described above, the SOH of the battery may be estimated by integrating the amount of electric current while the battery is charging/discharging and comparing the energy calculated from the accumulated electric current amount and the SOC variation while integrating the amount of electric current. Therefore, to accurately estimate the SOH of the battery, the SOC of the battery should be first estimated, and in the case of measuring the SOC of the battery based on the open circuit voltage, a waiting time until the battery enters a stable state may be required.

The battery management system installed in the system together with the battery may determine whether it is possible to estimate the SOH from the battery (S22). For example, when the SOC of the battery may be accurately measured, the SOH of the battery may be estimated using the SOC measured from the battery and the electric current integration amount (S23). On the other hand, in the case in which the standby time does not elapse or it is not possible to wait until the standby time elapses, the SOH may be estimated based on the system usage without the electric current integration amount and the SOC (S24). The server may receive an estimate for the SOH from each of the systems via the network.

Also, the server may create a usage scenario for each of the groups determined in operation S21 above (S25). Based on the usage scenario, data that may be input to the lifespan prediction model, for example, an SOC profile, is created, and the lifespan prediction model mounted in the server receives the estimated value of the SOH of the battery and the data extracted from the usage scenario, and may predict the end-of-life time (S26).

The server may output battery information and end-of-life time to the user through the network (S27). For example, the server may output battery information indicating the state of the battery and the end-of-life time to a display of the system or a mobile device interlocked with the system through a network.

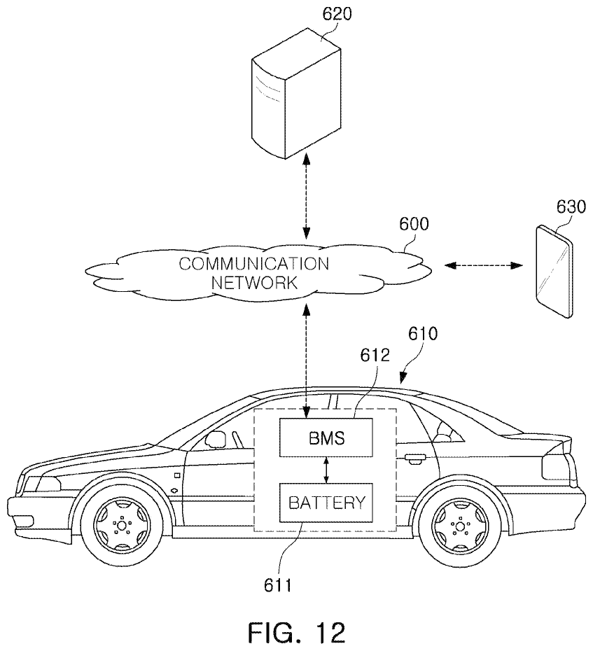

FIG. 12 is a diagram illustrating a method of predicting the lifespan of a battery according to an embodiment.

Referring to FIG. 12, a system 610 equipped with a battery 611 and a battery management system 612 may be connected to a server 620 through a communication network 600. As an example, the battery management system 612 is connected to the server 620 to communicate with each other through the communication network 600, and a user terminal 630 owned by the user of the system 610 is also connected to the communication network 600.

The battery management system 612 may control charging and discharging of the battery 611, collect raw data from the battery 611, and transmit the collected data to the server 620. The server 620 may execute a lifespan prediction model for predicting the lifespan of the battery 611 mounted in the system 610. For example, the server 620 may extract characteristic information from the raw data received from the battery management system 612 and may group the system 610 using the characteristic information.

For example, the server 620 may be connected to a plurality of other electric vehicles that are the same as or similar to the system 610 through the communication network 600, and the server 620 extracts characteristic information from the raw data received from respective electric vehicles to group the electric vehicles. As described above, the electric vehicles may be grouped according to usages such as commuting and leisure, driving regions, or the like.

When the grouping of the system 610 is completed, the server 620 may generate a future usage scenario for the group to which the system 610 belongs, generate data corresponding to the usage scenario, and input the data into the lifespan prediction model. The lifespan prediction model may predict a change in SOH of the battery 611 based on the received data, determine the end-of-life time of the battery 611 based on the predicted SOH change, and transfer the same to the user of the system 610. For example, the end-of-life time may be transmitted to the user terminal 630 or the like owned by the user through the communication network 600.

As set forth above, according to embodiments, the systems are divided into a plurality of groups according to the usage patterns collected from respective systems equipped with batteries, and a battery usage scenario may be generated according to respective usage environments and usage patterns of the plurality of groups. By inputting usage scenarios into a pre-trained machine learning model along with the SOH estimated from the battery, the end-of-life time of the battery may be accurately predicted, and batteries installed in electric vehicles/energy storage devices may be stably operated and managed.

The disclosed technology can be implemented in rechargeable secondary batteries that are widely used in battery-powered devices or systems, including, e.g., digital cameras, mobile phones, notebook computers, hybrid vehicles, electric vehicles, uninterruptible power supplies, battery storage power stations, and others including battery power storage for solar panels, wind power generators and other green tech power generators. Specifically, the disclosed technology can be implemented in some embodiments to provide improved electrochemical devices such as a battery used in various power sources and power supplies, thereby mitigating climate changes in connection with uses of power sources and power supplies. Lithium secondary batteries based on the disclosed technology can be used to address various adverse effects such as air pollution and greenhouse emissions by powering electric vehicles (EVs) as alternatives to vehicles using fossil fuel-based engines and by providing battery based energy storage systems (ESSs) to store renewable energy such as solar power and wind power. While examples of embodiments of the disclosed technology have been illustrated and described above, various modifications and variations to the disclosed embodiments and other embodiments could be made based on what is disclosed in this patent document.

What is claimed is:

1. A method of predicting a lifespan of each of batteries respectively connected in a plurality of systems, comprising:
estimating a state of health (SOH) of a battery in one of the plurality of systems by integrating an amount of an electric current of the battery while a state of charge (SOC) of the battery changes;
dividing the plurality of systems into a plurality of groups according to a usage pattern collected by each of the plurality of systems at every predetermined period;
generating a usage scenario of the battery in each of the plurality of systems, using a usage environment of each of the plurality of groups and the usage pattern; and
predicting, for each of the plurality of systems, lifespan information of the battery using the usage scenario and the SOH of the battery.

2. The method of claim 1, wherein the estimating of the SOH of the battery includes,
calculating a charging energy or a discharging energy of the battery by accumulating a charging electric current or a discharging electric current, respectively, while the SOC of the battery is changing,
calculating a first energy of the battery corresponding to a fully charged state of the battery using the charging energy or the discharging energy, and
calculating the SOH of the battery by comparing the first energy with a second energy of the battery corresponding to a fully charged state at a time of shipment of the battery.

3. The method of claim 1, wherein the usage pattern includes a charging pattern and a discharging pattern of the battery mounted in each of the plurality of systems.

4. The method of claim 1, wherein each of the plurality of systems is an electric vehicle, and the usage scenario includes a use of the battery, a driving profile, a mileage, a driving environment, a charging habit of the electric vehicle, or combinations thereof.

5. The method of claim 4, wherein the driving profile and the mileage vary depending on a use of the electric vehicle, and the driving environment varies depending on a driving area of the electric vehicle.

6. The method of claim 1, wherein each of the plurality of systems is an energy storage device, and the usage scenario includes equipment using the energy storage device as a power source, a surrounding environment in which the equipment operates, or combinations thereof.

7. The method of claim 1, wherein each of the plurality of systems is an electric vehicle, and the SOH is estimated after the electric vehicle stops and a predetermined stabilization time elapses.

8. The method of claim 1, wherein the plurality of systems divided into the plurality of groups are updated according to the usage pattern collected by each of the plurality of systems at every predetermined period.

9. The method of claim 1, wherein an end-of-life time included in the lifespan information is predicted in a predetermined cycle unit.

10. A battery management system for managing batteries respectively connected in a plurality of systems comprising:
a state of health (SOH) estimation model estimating an SOH of a battery connected in one of the systems by integrating an amount of an electric current of the battery while an SOC of the battery-changes;
a scenario generation model classifying the plurality of systems into a plurality of groups based on a usage pattern collected from each of the plurality of systems, and generating a usage scenario of the battery according to a usage environment and a usage pattern of each of the plurality of groups; and
a lifespan prediction model predicting an end-of-life time of the battery using the SOH of the battery estimated by the SOH estimation model and the usage scenario.

11. The battery management system of claim 10, wherein the SOH estimation model, the scenario generation model, and the lifespan prediction model are stored and executed in a server connected to a network that is communicable, and
the server is connected to a terminal that collects the SOC of the battery, the amount of electric current of the battery, the usage pattern of the battery and the usage environment of each of the plurality of groups in each of the plurality of systems, through the network.

12. The battery management system of claim 11, wherein the server guides the end-of-life time to administrators of the plurality of systems through the network.

13. The battery management system of claim 11, wherein the server receives and stores access information for an administrator of one or more systems among the plurality of systems from the administrator, and transmits the end-of-life time to a mobile device of the administrator.

14. The battery management system of claim 10, wherein the scenario generation model divides the plurality of systems into the plurality of groups based on a charging pattern and a discharging pattern of the battery, and generates the usage scenario according to a usage environment of the plurality of systems, a surrounding charging infrastructure, a type of the plurality of systems, or combinations thereof.

15. The battery management system of claim 10, wherein the scenario generation model collects the usage pattern at every predetermined period, re-classifies the plurality of systems into the plurality of groups, and regenerates the usage scenario at the predetermined period, and
the lifespan prediction model predicts the end-of-life time at every predetermined period, based on the SOH of the battery estimated by the SOH estimation model during the predetermined period and the usage scenario regenerated by the scenario generation model.

16. A battery management method executed in a server communicatively connected to a system including a battery and a battery management system, the battery management method comprising:
receiving raw data collected from the battery by the battery management system for a predetermined period of time;
extracting characteristic information from the raw data;
grouping the system into a predetermined group based on the characteristic information;
generating a usage scenario to be applied to the group by inputting the characteristic information into a scenario generation model;
predicting a remaining lifespan of the battery by inputting the usage scenario into a lifespan prediction model; and
transmitting the remaining lifespan of the battery to a communication terminal of a user of the system through a communication network.

17. The battery management method of claim 16, wherein when the system is a new system newly connected to the server, the new system is grouped by comparing the characteristic information of an existing system already connected to the server with the characteristic information of the new system.

18. The battery management method of claim 16, wherein the characteristic information includes a usage pattern of the battery mounted in the system.
